(19) United States
(12) Patent Application Publication
(10) Pub. No.: US 2008/0238560 A1
(43) Pub. Date: Oct. 2, 2008

(54) Voltage-controlled oscillator and method of operating the same

(75) Inventor: Toru Shibata, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/076,405

(22) Filed: Mar. 18, 2008

(30) Foreign Application Priority Data
Mar. 30, 2007 (JP) 2007-094501

(51) Int. Cl. H03B 7/00

(52) U.S. Cl. 331/132

(57) ABSTRACT

A voltage-controlled oscillator has: an LC resonant circuit including an inductor and a variable capacitor that are connected in parallel between a pair of output terminals; a plurality of negative resistance circuits provided between a power source and the LC resonant circuit; a plurality of capacitor groups; a first switch circuit selecting an arbitrary number of negative resistance circuit from the plurality of negative resistance circuits; and a second switch circuit selecting an arbitrary number of capacitor group from the plurality of capacitor groups. The LC resonant circuit and the selected capacitor group constitute a resonant circuit. The resonant circuit is electrically connected to the power source through the selected negative resistance circuit, oscillates at an oscillation frequency depending on total capacitance of the resonant circuit, and outputs a differential signal of the oscillation frequency from the pair of output terminals.

### BACKGROUND OF THE INVENTION

1. Field of the Invention

The present invention relates to a voltage-controlled oscillator (VCO). In particular, the present invention relates to a voltage-controlled oscillator utilizing an LC resonant circuit.

This application is based upon and claims the benefit of priority from Japanese patent application No. 2007-094501, filed on Mar. 30, 2007, the disclosure of which is incorporated herein in its entirely by reference.

2. Description of Related Art

A PLL (Phase Locked Loop) circuit is capable of outputting an output signal whose frequency is an integral multiple of a frequency of an input signal. For example, the PLL circuit is applied to a micro processor and used for generating an internal clock whose frequency is an integral multiple of an external clock frequency to speed up the micro processor. Also, many high-speed devices such as a SerDes (Serializer/Deserializer) employ the PLL circuit.

The PLL circuit includes a voltage-controlled oscillator (VCO) that outputs an output signal whose frequency varies depending on an input voltage. A voltage-controlled oscillator utilizing an LC resonant circuit is in widespread use. Such a voltage-controlled oscillator using an LC resonant circuit is disclosed in Japanese Laid Open Patent Application JP-P2004-140471.

FIG. 1 is a prototype circuit diagram showing a configuration of a voltage-controlled oscillator 200. The voltage-controlled oscillator 200 is provided with an LC resonant circuit 10, a P-channel cross-coupled transistor 20 and an N-channel cross-coupled transistor 30 that function as negative resistances, and capacitor switch groups 410 and 420.

The LC resonant circuit 10 includes an inductor L10 and variable capacitors C10 and C20 that are connected in parallel between output terminals 60 and 70. The LC resonant circuit 10 is connected to a first power source VDD (hereinafter referred to as a power source VDD) through the P-channel cross-coupled transistor 20 as a negative resistance and to a second power source VSS (hereinafter referred to as a power source VSS) through the N-channel cross-coupled transistor 30 as a negative resistance. The variable capacitors C10 and C20 are connected with each other through a control voltage input terminal 50. Capacitance values of the variable capacitors C10 and C20 vary depending on a control voltage input to the control voltage input terminal 50.

The P-channel cross-coupled transistor 20 includes P-channel MOS transistors P10 and P20 (hereinafter referred to as transistors P10 and P20) which constitute the negative resistance. More specifically, sources of the transistors P10 and P20 are connected to the power source VDD. A drain of the transistor P10 is connected to the output terminal 70, and a gate of the transistor P10 is connected to the output terminal 60. A drain of the transistor P20 is connected to the output terminal 60, and a gate of the transistor P20 is connected to the output terminal 70. That is to say, the transistors P10 and P20 are connected in a cross-coupled manner.

Similarly, the N-channel cross-coupled transistor 30 includes N-channel MOS transistors N10 and N20 (hereinafter referred to as transistors N10 and N20) which constitute the negative resistance. More specifically, sources of the transistors N10 and N20 are connected to the power source VSS. A drain of the transistor N10 is connected to the output terminal 70, and a gate of the transistor N10 is connected to the output terminal 60. A drain of the transistor N20 is connected to the output terminal 60, and a gate of the transistor N20 is connected to the output terminal 70. That is to say, the transistors N10 and N20 are connected in a cross-coupled manner.

The gates of the transistor P10 and the transistor N10 are connected with each other and to the output terminal 60. Similarly, the gates of the transistor P20 and the transistor N20 are connected with each other and to the output terminal 70.

The capacitor switch group 410 includes a plurality of capacitors C110 to C113 provided between the output terminal 70 and the power source VSS and a plurality of switches S110 to S113. The plurality of capacitors C110 to C113 are connected to the power source VSS through the plurality of switches S110 to S113, respectively. The plurality of switches S110 to S113 are ON/OFF controlled by respective switch control signals SW000 to SW300 and selectively connect the capacitors C110 to C113 with the power source VSS.

Similarly, the capacitor switch group 420 includes a plurality of capacitors C120 to C123 provided between the output terminal 60 and the power source VSS and a plurality of switches S120 to S123. The plurality of capacitors C120 to C123 are connected to the power source VSS through the plurality of switches S120 to S123, respectively. The plurality of switches S120 to S123 are ON/OFF controlled by respective switch control signals SW000 to SW300 and selectively connect the capacitors C120 to C123 with the power source VSS.

The voltage-controlled oscillator 200 thus constructed oscillates at a resonance frequency of the LC resonant circuit 10, and clock signals of the resonance frequency are output as a differential signal from the output terminals 60 and 70. Here, the resonance frequency varies depending on the capacitance values of the variable capacitors C10 and C20. In other words, an oscillation frequency of the differential signal varies depending on the control voltage input to the control voltage input terminal 50.

Moreover, the capacitors in the capacitor switch groups 410 and 420 are selectively incorporated into the LC resonant circuit 10 in accordance with the switch control signals SW000 to SW300. The resonance frequency of the LC resonant circuit 10 varies depending on a total capacitance value of the incorporated capacitors. It is therefore possible by using the switch control signals SW000 to SW300 to discretely control the oscillation frequency of the voltage-controlled oscillator 200, as shown in FIG. 2. In FIG. 2, the variable range of the oscillation frequency is +5 to 10%. For example, when all the switches S110 to S113 and S120 to S123 are turned ON and thereby all the capacitors C110 to C113 and C120 to C123 are incorporated into the resonant circuit, the oscillation frequency of the differential signal becomes relatively low because the total capacitance value of the whole resonant circuit becomes larger. On the other hand, when all the switches S110 to S113 and S120 to S123 are turned OFF and none of the capacitors C110 to C113 and C120 to C123 is incorporated into the resonant circuit, the oscillation frequency of the differential signal becomes relatively high because the total capacitance value of the whole resonant circuit becomes smaller.

In general, a voltage-controlled oscillator utilizing an LC resonant circuit has the following advantages as compared with a voltage-controlled oscillator utilizing a ring oscillator. A first advantage is that a higher oscillation frequency can be obtained. A second advantage is less noise. A third advantage is that changes in the oscillation frequency (frequency variation width) corresponding to changes in the control voltage are small and thus variations in the oscillation frequency in response to noises superimposed on the control voltage are small. However, the third advantage can reversely be the following disadvantage. That is, it is difficult to realize an oscillation frequency required in a device or an application by controlling the control voltage, since the changes in the oscillation frequency corresponding to the changes in the control voltage are small. In order to cover the disadvantage, the above-described voltage-controlled oscillator 200 is provided with the capacitor switch groups 410 and 420. By using the capacitor switch groups 410 and 420 together with the LC resonant circuit 10, it becomes possible to control the oscillation frequency within the variable range of +5 to 10%.

The inventor of the present application has recognized the following points. In the case of the above-described voltage-controlled oscillator 200, the variable range of the oscillation frequency is about ±10% at a maximum. It may be possible to enlarge the frequency variable range by increasing the maximum capacitance values of the capacitor switch groups 410 and 420. However, if the capacitance values are increased, the resonant circuit may not satisfy an oscillation condition (gm/gl≧1, wherein gm is a mutual conductance of the cross-coupled transistor and gl is a conductance of the whole resonant circuit) and stop the oscillation.

There is a case where a product is required to support various applications. In this case, the PLL circuit in the product needs to output signals of every frequency required by the various applications. That is to say, the voltage-controlled oscillator needs to oscillate at every frequency required by the various applications. Therefore, a voltage-controlled oscillator that can oscillate within a wider frequency variable range is desired.

### SUMMARY

In one embodiment of the present invention, a voltage-controlled oscillator is provided. The voltage-controlled oscillator has: an LC resonant circuit including an inductor and a variable capacitor that are connected in parallel between a pair of output terminals, wherein capacitance of the variable capacitor varies depending on an input voltage; a plurality of negative resistance circuits provided between a power source and the LC resonant circuit; a plurality of capacitor groups; a first switch circuit configured to select an arbitrary number of negative resistance circuit from the plurality of negative resistance circuits; and a second switch circuit configured to select an arbitrary number of capacitor group from the plurality of capacitor groups. The LC resonant circuit and the selected capacitor group constitute a resonant circuit. The resonant circuit is electrically connected to the power source through the selected negative resistance circuit, oscillates at an oscillation frequency depending on total capacitance of the resonant circuit, and outputs a differential signal of the oscillation frequency from the pair of output terminals.

In another embodiment of the present invention, a method of operating a voltage-controlled oscillator is provided. The voltage-controlled oscillator has an LC resonant circuit including an inductor and a variable capacitor that are connected in parallel between a pair of output terminals. The method of operating the voltage-controlled oscillator includes: (A) selecting an arbitrary number of capacitor group from a plurality of capacitor groups such that the LC resonant circuit and the selected capacitor group constitute a resonant circuit; (B) selecting an arbitrary number of negative resistance circuit from a plurality of negative resistance circuits such that the resonant circuit is electrically connected to a power source through the selected negative resistance circuit; (C) changing capacitance of the variable capacitor depending on an input voltage; (D) oscillating by the resonant circuit at an oscillation frequency depending on total capacitance of the resonant circuit; and (E) outputting a differential signal of the oscillation frequency from the pair of output terminals.

According to the present invention, it is possible to enlarge the variable range of the oscillation frequency of the voltage-controlled oscillator.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a prototype circuit diagram showing a configuration of a voltage-controlled oscillator;

FIG. 2 shows a variable range of an oscillation frequency of the voltage-controlled oscillator shown in FIG. 1;

FIG. 3 is a block diagram showing a configuration example of a PLL circuit according to an embodiment of the present invention;

FIG. 4 is a circuit diagram showing a configuration example of a voltage-controlled oscillation circuit in a voltage-controlled oscillator according to the embodiment of the present invention;

FIG. 5 is a circuit diagram showing a configuration example of a selection circuit in the voltage-controlled oscillator according to the embodiment of the present invention;

FIG. 6 shows a variable range of an oscillation frequency of the voltage-controlled oscillator according to the embodiment of the present invention;

FIGS. 7A and 7B are circuit diagrams showing another configuration example of the voltage-controlled oscillation circuit in the voltage-controlled oscillator according to the embodiment of the present invention; and

FIG. 8 is a circuit diagram showing another configuration example of the selection circuit in the voltage-controlled oscillator according to the embodiment of the present invention.

### DETAILED DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

### 1. Configuration of PLL Circuit

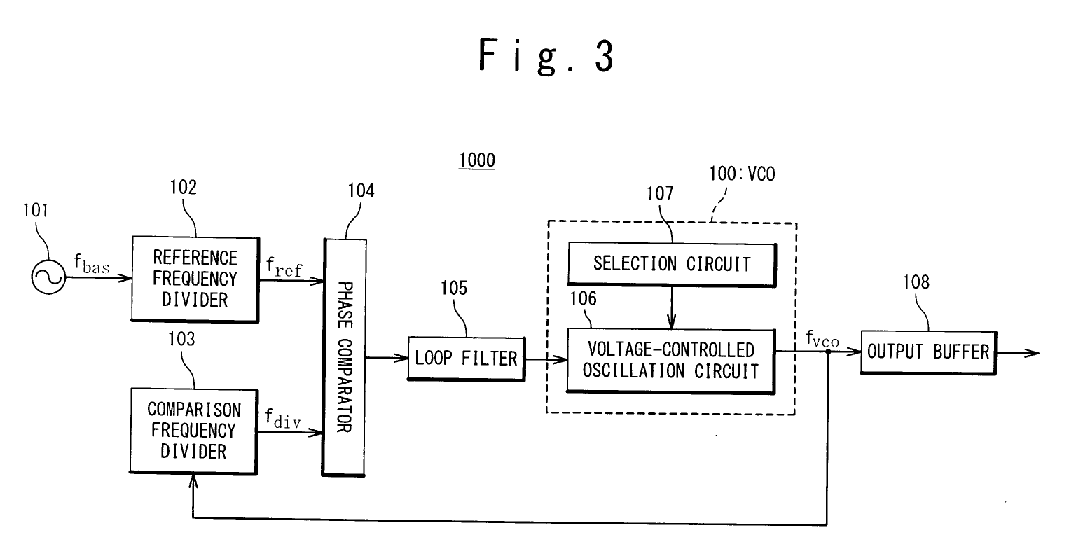

FIG. 3 is a block diagram showing a configuration example of a PLL circuit 1000 according to the present embodiment. The PLL circuit 1000 shown in FIG. 3 is provided with a voltage-controlled oscillator 100, a reference frequency oscillator 101, a reference frequency divider 102, a comparison frequency divider 103, a phase comparator 104, a loop filter 105 and an output buffer 108. The voltage-controlled oscillator 100 includes a voltage-controlled oscillation circuit 106 and a selection circuit 107.

The reference frequency oscillator 101 is a highly stable oscillator such as a crystal oscillator and outputs a clock signal of a reference frequency f_{bas} to the reference frequency divider 102. The reference frequency divider 102 divides the reference frequency f_{bas} so as to obtain a comparison frequency f_{ref}. The comparison frequency divider 103 receives an output signal of an oscillation frequency f_{vco} from the voltage-controlled oscillation circuit 106 and divides the oscillation frequency f_{vco} so as to obtain a comparison frequency f_{div}. The phase comparator 104 compares the comparison frequency f_{div} with the comparison frequency f_{ref} and outputs a phase difference between them to the loop filter 105 through a charge pump (not shown). The loop filter 105 cuts off high-frequency components of the phase difference signal and outputs a voltage control signal for controlling the oscillation frequency f_{vco} of the voltage-controlled oscillation circuit 106.

The voltage-controlled oscillation circuit 106 receives the voltage control signal from the loop filter 105, and outputs the output signal of the oscillation frequency f_{vco} depending on the voltage control signal through the output buffer 108. As described later, the oscillation frequency f_{vco} in the present embodiment depends on not only the voltage control signal but also other control signals. The selection circuit 107 controls the voltage-controlled oscillation circuit 106 in accordance with the control signals (a mode signal Mode and switch control signals SW00 to SW30 which will be described later) and thereby controls the oscillation frequency f_{vco}.

### 2. Configuration of Voltage-Controlled Oscillation Circuit 106

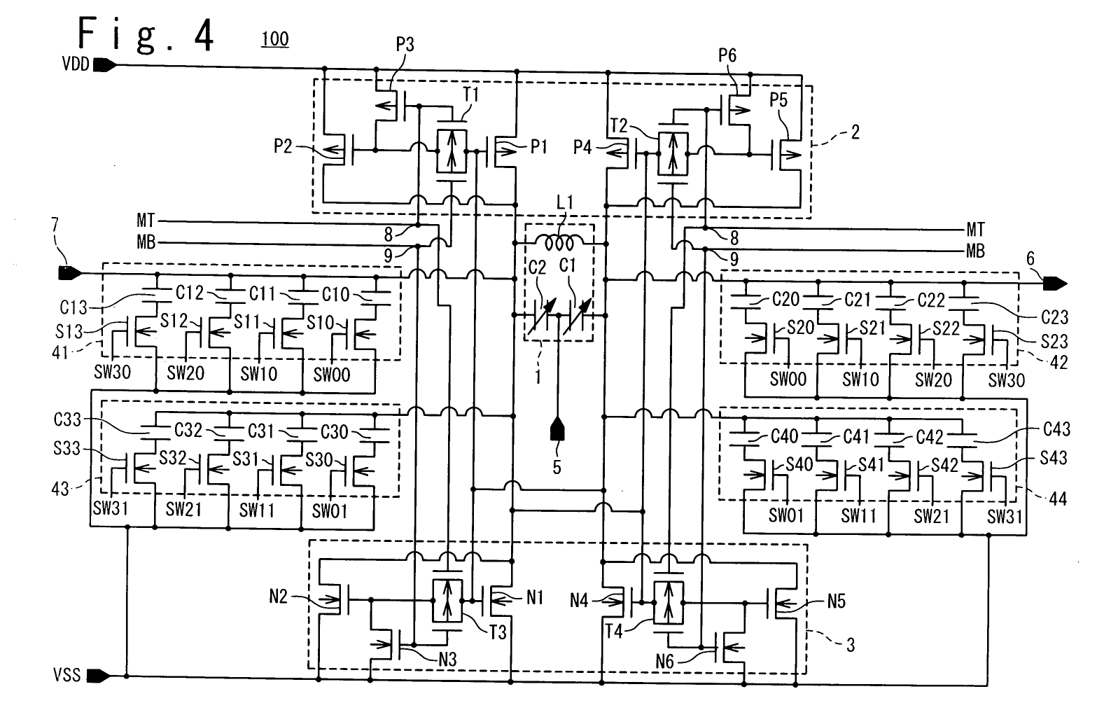

FIG. 4 is a circuit diagram showing a configuration of the voltage-controlled oscillation circuit 106 according to the present embodiment. The voltage-controlled oscillation circuit 106 shown in FIG. 4 is provided with an LC resonant circuit 1, a P-channel cross-coupled transistor 2, an N-channel cross-coupled transistor 3 and capacitor switch groups 41 to 44.

The LC resonant circuit 1 includes an inductor L1 and variable capacitors C1 and C2 that are connected in parallel between a pair of output terminals 6 and 7. The LC resonant circuit 1 is connected to a first power source VDD (hereinafter referred to as a power source VDD) through the P-channel cross-coupled transistor 2 serving as negative resistances and to a second power source VSS (hereinafter referred to as a power source VSS) through the N-channel cross-coupled transistor 3 serving as negative resistances. The variable capacitor C1 and the variable capacitor C2 are connected with each other through a control voltage input terminal 5. Capacitance values of the variable capacitors C1 and C2 vary depending on a control voltage input to the control voltage input terminal 5. As described later, the LC resonant circuit 1 and capacitors selected from the capacitor switch groups 41 to 44 constitute a “resonant circuit”.

The P-channel cross-coupled transistor 2 is provided with a plurality of negative resistance circuits and a first switch circuit. The plurality of negative resistance circuits are provided between the power source VDD and the LC resonant circuit 1. The first switch circuit selects an arbitrary number of negative resistance circuit from the plurality of negative resistance circuits and activates the selected negative resistance circuit. The LC resonant circuit 1 is electrically connected to the power source VDD through the selected negative resistance circuit.

In FIG. 4, the P-channel cross-coupled transistor 2 is provided with two P-channel cross-coupled transistors respectively serving as negative resistance circuits and a first switch circuit provided between the two P-channel cross-coupled transistors. More specifically, one P-channel cross-coupled transistor consists of P-channel MOS transistors P1 and P4, and the other P-channel cross-coupled transistor consists of P-channel MOS transistors P2 and P5. The first switch circuit includes transmission gates T1 and T2, and P-channel MOS transistors P3 and P6. The P-channel MOS transistors P1 to P6 are hereinafter referred to as transistors P1 to P6, respectively.

Sources of the respective transistors P1 to P6 are connected to the power source VDD. Drains of the transistors P1 and P2 are connected to the output terminal 7 and the LC resonant circuit 1. A gate of the transistor P1 is connected to the output terminal 6 and the LC resonant circuit 1, and a gate of the transistor P2 is connected to the output terminal 6 and the LC resonant circuit 1 through the transmission gate T1. A drain of the transistor P3 is connected to the gate of the transistor P2, and a gate of the transistor P3 is connected to a node 8 to which a mode signal MT is input. The transistor P3 functions as a switch element that controls electrical connection between the gate of the transistor P2 and the power source VDD in accordance with the mode signal MT input through the node 8.

Drains of the transistors P4 and P5 are connected to the output terminal 6 and the LC resonant circuit 1. A gate of the transistor P4 is connected to the output terminal 7 and the LC resonant circuit 1, and a gate of the transistor P5 is connected to the output terminal 7 and the LC resonant circuit 1 through the transmission gate T2. A drain of the transistor P6 is connected to the gate of the transistor P5, and a gate of the transistor P6 is connected to the node 8. The transistor P6 functions as a switch element that controls electrical connection between the gate of the transistor P5 and the power source VDD in accordance with the mode signal MT input through the node 8.

Each of the transmission gates T1 and T2 consists of an N-channel MOS transistor whose gate is connected to the node 8 and a P-channel MOS transistor whose gate is connected to a node 9. Input to the node 9 is a mode signal MB that is an inversion signal of the mode signal MT. The transmission gate T1 controls electrical connection between the gate of the transistor P2 and the output terminal 6 in accordance with the input mode signals MT and MB. The transmission gate T2 controls electrical connection between the gate of the transistor P5 and the output terminal 7 in accordance with the input mode signals MT and MB. Based on the mode signals MT and MB respectively input from the nodes 8 and 9, the first switch circuit can select an arbitrary number of negative resistance circuit from the plurality of negative resistance circuits and control the electrical connection between the power source VDD and the LC resonant circuit 1. For example, the first switch circuit can select the P-channel cross-coupled transistor (P2 and P5) by turning ON the transmission gates T1 and T2.

The N-channel cross-coupled transistor 3 is provided with a plurality of negative resistance circuits and a first switch circuit. The plurality of negative resistance circuits are provided between the power source VSS and the LC resonant circuit 1. The first switch circuit selects an arbitrary number of negative resistance circuit from the plurality of negative resistance circuits and activates the selected negative resistance circuit. The LC resonant circuit 1 is electrically connected to the power source VSS through the selected negative resistance circuit.

In FIG. 4, the N-channel cross-coupled transistor 3 is provided with two N-channel cross-coupled transistors respectively serving as negative resistance circuits and a first switch circuit provided between the two N-channel cross-coupled transistors. More specifically, one N-channel cross-coupled transistor consists of N-channel MOS transistors N1 and N4, and the other N-channel cross-coupled transistor consists of N-channel MOS transistors N2 and N5. The first switch circuit includes transmission gates T3 and T4, and N-channel MOS transistors N3 and N6. The N-channel MOS transistors N1 to N6 are hereinafter referred to as transistors N1 to N6, respectively.

Sources of the respective transistors N1 to N6 are connected to the power source VSS. Drains of the transistors N1 and N2 are connected to the output terminal 7 and the LC resonant circuit 1. A gate of the transistor N1 is connected to the output terminal 6 and the LC resonant circuit 1, and a gate of the transistor N2 is connected to the output terminal 6 and the LC resonant circuit 1 through the transmission gate T3. A drain of the transistor N3 is connected to the gate of the transistor N2, and a gate of the transistor N3 is connected to the node 9 to which the mode signal MB is input. The transistor N3 functions as a switch element that controls electrical connection between the gate of the transistor N2 and the power source VSS in accordance with the mode signal MB.

Drains of the transistors N4 and N5 are connected to the output terminal 6 and the LC resonant circuit 1. A gate of the transistor N4 is connected to the output terminal 7 and the LC resonant circuit 1, and a gate of the transistor N5 is connected to the output terminal 7 and the LC resonant circuit 1 through the transmission gate T4. A drain of the transistor N6 is connected to the gate of the transistor N5, and a gate of the transistor N6 is connected to the node 9. The transistor N6 functions as a switch element that controls electrical connection between the gate of the transistor N5 and the power source VSS in accordance with the mode signal MB.

Each of the transmission gates T3 and T4 consists of an N-channel MOS transistor whose gate is connected to the node 8 and a P-channel MOS transistor whose gate is connected to the node 9. The transmission gate T3 controls electrical connection between the gate of the transistor N2 and the output terminal 6 in accordance with the input mode signals MT and MB. The transmission gate T4 controls electrical connection between the gate of the transistor N5 and the output terminal 7 in accordance with the input mode signals MT and MB. Based on the mode signals MT and MB respectively input from the nodes 8 and 9, the first switch circuit can select an arbitrary number of negative resistance circuit from the plurality of negative resistance circuits and control the electrical connection between the power source VSS and the LC resonant circuit 1. For example, the first switch circuit can select the N-channel cross-coupled transistor (N2 and N5) by turning ON the transmission gates T3 and T4.

The voltage-controlled oscillation circuit 106 according to the present embodiment is provided with a plurality of capacitor switch groups and a second switch circuit. In FIG. 4, the voltage-controlled oscillation circuit 106 is provided with four capacitor switch groups 41 to 44. Each of the capacitor switch groups 41 to 44 includes a plurality of capacitors and a plurality of switches. The plurality of switches in each capacitor switch group constitute the second switch circuit. The second switch circuit can select an arbitrary number of capacitor switch group from the capacitor switch groups 41 to 44, and the selected capacitor switch group is to be incorporated into a “resonant circuit” including the LC resonant circuit 1. In other words, the LC resonant circuit 1 and the selected capacitor switch group constitute the resonant circuit. More specifically, the second switch circuit can select an arbitrary number of capacitor from the plurality of capacitors in the respective capacitor switch groups 41 to 44 in accordance with switch control signals. In FIG. 4, the capacitors in each of the capacitor switch groups 41 and 42 are selected in accordance with switch control signals SW00 to SW30, while the capacitors in each of the capacitor switch groups 43 and 44 are selected in accordance with switch control signals SW01 to SW31. Any capacitor switch group that includes the selected capacitor becomes the “selected capacitor switch group”. The second switch circuit selects the selected capacitor in each of the selected capacitor switch group, and the selected capacitor in each of the selected capacitor switch group and the LC resonant circuit 1 constitute the “resonant circuit”.

As shown in FIG. 4, the capacitor switch group 41 includes a plurality of capacitors C10 to C13 provided between the output terminal 7 and the power source VSS, and a plurality of switches S10 to S13 as the second switch circuit. The plurality of capacitors C10 to C13 are connected to the power source VSS through the plurality of switches S10 to S13, respectively. The plurality of switches S10 to S13 are ON/OFF controlled by the respective switch control signals SW00 to SW30 and selectively connect the capacitors C10 to C13 with the power source VSS. In other words, the switch control signals SW00 to SW30 are respectively related to the capacitors C10 to C13, and the second switch circuit selects the capacitor in response to the switch control signals SW00 to SW30. Thus, the capacitors C10 to C13 are selectively incorporated into the resonant circuit in accordance with the switch control signals SW00 to SW30.

The capacitor switch group 42 includes a plurality of capacitors C20 to C23 provided between the output terminal 6 and the power source VSS, and a plurality of switches S20 to S23 as the second switch circuit. The plurality of capacitors C20 to C23 are connected to the power source VSS through the plurality of switches S20 to S23, respectively. The plurality of switches S20 to S23 are ON/OFF controlled by the respective switch control signals SW00 to SW30 and selectively connect the capacitors C20 to C23 with the power source VSS. In other words, the switch control signals SW00 to SW30 are respectively related to the capacitors C20 to C23, and the second switch circuit selects the capacitor in response to the switch control signals SW00 to SW30. Thus, the capacitors C20 to C23 are selectively incorporated into the resonant circuit in accordance with the switch control signals SW00 to SW30.

The capacitor switch group 43 includes a plurality of capacitors C30 to C33 provided between the output terminal 7 and the power source VSS, and a plurality of switches S30 to S33 as the second switch circuit. The plurality of capacitors C30 to C33 are connected to the power source VSS through the plurality of switches S30 to S33, respectively. The plurality of switches S30 to S33 are ON/OFF controlled by the respective switch control signals SW01 to SW31 and selectively connect the capacitors C30 to C33 with the power source VSS. In other words, the switch control signals SW01 to SW31 are respectively related to the capacitors C30 to C33, and the second switch circuit selects the capacitor in response to the switch control signals SW01 to SW31. Thus, the capacitors C30 to C33 are selectively incorporated into the resonant circuit in accordance with the switch control signals SW01 to SW31.

The capacitor switch group 44 includes a plurality of capacitors C40 to C43 provided between the output terminal 6 and the power source VSS, and a plurality of switches S40 to S43 as the second switch circuit. The plurality of capacitors C40 to C43 are connected to the power source VSS through the plurality of switches S40 to S43, respectively. The plurality of switches S40 to S43 are ON/OFF controlled by the respective switch control signals SW01 to SW31 and selectively connect the capacitors C40 to C43 with the power source VSS. In other words, the switch control signals SW01 to SW31 are respectively related to the capacitors C40 to C43, and the second switch circuit selects the capacitor in response to the switch control signals SW01 to SW31. Thus, the capacitors C40 to C43 are selectively incorporated into the resonant circuit in accordance with the switch control signals SW01 to SW31.

It is preferable that the respective switches S10 to S13, S20 to S23, S30 to S33 and S40 to S43 are configured by transistors of the same conductivity type. For example, the respective switches are N-channel MOS transistors. By employing the same conductivity type, configurations of the switches S10 to S13, S20 to S23, S30 to S33 and S40 to S43 and an output control of the switch control signals SW00 to SW30 and SW01 to SW31 can be simplified.

### 3. Configuration of Selection Circuit 107

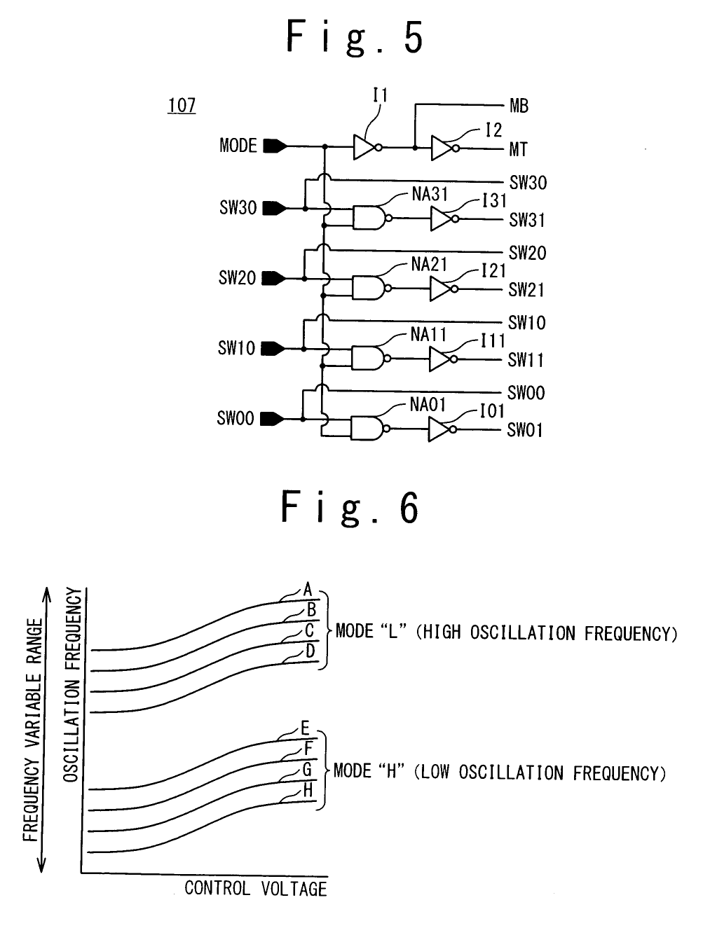

FIG. 5 is a block diagram showing a configuration example of the selection circuit 107 according to the present embodiment. The selection circuit 107 generates the above-mentioned mode signals MB and MT, switch control signals SW00 to SW30 and SW01 to SW31. More specifically, the selection circuit 107 receives a mode signal MODE and the switch control signals SW00 to SW30 from the outside. The mode signal MODE specifies an operation mode of the voltage-controlled oscillator 100 which can operate in a plurality of modes. Based on the received mode signal MODE and switch control signals SW00 to SW30, the selection circuit 107 generates the above-mentioned mode signals MB and MT, switch control signals SW00 to SW30 and SW01 to SW31. The mode signals MB and MT specify the negative resistance circuit to be selected by the above-mentioned first switch circuit. The switch control signals SW00 to SW30 and SW01 to SW31 specify the capacitor and the capacitor switch group to be selected by the above-mentioned second switch circuit and to be incorporated into the resonant circuit.

In FIG. 5, the selection circuit 107 is provided with inverters I1 and I2, NAND gates NA01 to NA31 and inverters I01 to I31. The inverter I1 receives the mode signal MODE and outputs the mode signal MB that is an inversion signal of the mode signal MODE. The inverter I2 receives the mode signal MB from the inverter I1 and outputs the mode signal MT that is an inversion signal of the mode signal MB. The NAND gates NA01 to NA31 respectively receive the switch control signals SW00 to SW30 together with the mode signal MODE and output respective results of negative AND operation. The inverters I01 to I31 respectively receive output signals from the NAND gates NA01 to NA31 and output the inversion signals as the switch control signals SW01 to SW31. The selection circuit 107 thus constructed outputs the mode signal MT to the node 8 and the mode signal MB to the node 9. Moreover, the selection circuit 107 outputs the switch control signals SW00 to SW30 and SW01 to SW31 to the related switches in the capacitor switch groups 41 to 44.

The switch control signals SW00 to SW30 are signals for controlling ON/OFF of the switches S10 to S13 and S20 to S23. In the case where the switches S10 to S13 and S20 to S23 are N-channel MOS transistors, the respective switch control signals SW00 to SW30 input to the selection circuit 107 are set to High level when the related capacitors in the capacitor switch groups 41 and 42 are selected, while set to Low level when the related capacitors in the capacitor switch groups 41 and 42 are not selected.

The switch control signals SW01 to SW31 are signals for controlling ON/OFF of the switches S30 to S33 and S40 to S43. Signal levels (High or Low) of the respective switch control signals SW01 to SW31 are determined depending on the mode signal MODE and the respective switch control signals SW00 to SW30 input to the selection circuit 107. In a case where the mode signal MODE is High level, the signal levels of the switch control signals SW01 to SW31 become equal to those of the switch control signals SW00 to SW30, respectively. Therefore, the capacitor incorporated into the resonant circuit can be selected from all of the capacitor switch groups 41 to 44, i.e., any of the capacitor switch groups 41 to 44 can be the selected capacitor switch group. On the other hand, in a case where the mode signal MODE is Low level, the switch control signals SW01 to SW31 become Low level regardless of the signal levels of the switch control signals SW00 to SW30. Therefore, the capacitor incorporated into the resonant circuit can be selected only from the capacitor switch groups 41 and 42, i.e., only the capacitor switch groups 41 and 42 can be the selected capacitor switch group. In this manner, the number of the selected capacitor switch group can be varied depending on the mode signal MODE.

It should be noted that the signal levels (High or Low) of the switch control signals SW00 to SW30 input to the selection circuit 107 are controlled independently from each other. Therefore, the capacitor to be incorporated into the resonant circuit can be arbitrarily selected from the capacitors C10 to C13 (C20 to C23) in the capacitor switch group 41 (42). Moreover, since the switch control signals SW00 to SW30 are independent from each other, the switch control signals SW01 to SW31 can also be controlled independently from each other. Therefore, the capacitor to be incorporated into the resonant circuit can be arbitrarily selected from the capacitors C30 to C33 (C40 to C43) in the capacitor switch group 43 (44). That is to say, an arbitral number of capacitor can be selected from each capacitor switch group by the second switch circuit.

### 4. Operation of Voltage-Controlled Oscillator

As described above, the number of the negative resistance circuit selected by the first switch circuit varies depending on the mode signals MT and MB. Since the mode signals MT and MB are generated from the mode signal MODE, it can be said that the first switch circuit selects the negative resistance circuit based on the mode signal MODE, and the number of the selected negative resistance circuit depends on the mode signal MODE. Moreover, the number of the capacitor switch group selected by the second switch circuit varies depending on the mode signal MODE. That is to say, both of the number of the selected negative resistance circuit and the number of the selected capacitor switch group depend on the mode signal MODE. The number of the selected negative resistance circuit corresponds to the number of the selected capacitor switch group.

The LC resonant circuit 1 and the selected capacitor switch group constitute the above-mentioned resonant circuit. The resonant circuit is electrically connected to the power source VDD and VSS through the selected negative resistance circuit. Then, the resonant circuit oscillates at an oscillation frequency f_{vco} and outputs a differential signal of the oscillation frequency f_{vco} from the pair of output terminals 6 and 7.

It should be noted here that the oscillation frequency f_{vco} depends on the total capacitance of the resonant circuit. The resonant circuit includes not only the variable capacitors C1 and C2 but also the selected capacitor switch group. The capacitance values of the variable capacitors C1 and C2 are changed by the control voltage input to the control voltage input terminal 5. On the other hand, the number of the selected capacitor switch group is changed by the mode signal MODE. Therefore, the oscillation frequency f_{vco} can be changed by not only the input control voltage but also the mode signal MODE. When the mode signal MODE is set to Low level and the smaller number of capacitor switch groups (41 and 42) are selectively incorporated into the resonant circuit, the oscillation frequency f_{vco} can vary in a higher frequency range (MODE “L”: High Frequency Mode). On the other hand, when the mode signal MODE is set to High level and the larger number of capacitor switch groups (41, 42, 43 and 44) are selectively incorporated into the resonant circuit, the oscillation frequency f_{vco} can vary in a lower frequency range (MODE “H”: Low Frequency Mode).

In this manner, the voltage-controlled oscillator 100 according to the present embodiment can operate in a plurality of modes (High Frequency Mode and Low Frequency Mode) in accordance with the mode signal MODE. The mode signal MODE specifies an operation mode of the voltage-controlled oscillator 100 and determines the frequency variable range of the oscillation frequency f_{vco} of the voltage-controlled oscillator 100. The number of the capacitor switch group selected by the second switch circuit is different between the plurality of modes and is changed depending on the operation mode of the voltage-controlled oscillator 100. Moreover, the number of the selected negative resistance circuit, which corresponds to the number of the selected capacitor switch group, is also different between the plurality of modes and changed depending on the operation mode. This secures sufficient driving capability necessary for driving the resonant circuit that includes the selected capacitor switch group whose number is different depending on the operation mode.

The high frequency mode and the low frequency mode according to the present embodiment will be described below in detail with reference to FIGS. 4 to 6.

### (High Frequency Mode)

In the case of the high frequency mode, the mode signal MODE of Low level is input to the selection circuit 107. Therefore, the mode signal MT of Low level and the mode signal MB of High level are input to the voltage-controlled oscillation circuit 106. In this case, the transmission gates T1 to T4 are turned OFF (High-impedance) in response to the mode signals MT and MB, and hence the electrical connections between the gates of the transistors P1 and P2, the transistors P4 and P5, the transistors N1 and N2 and the transistors N4 and N5 are cut off. Also, the transistors P3 and P6 are turned ON in response to the mode signal MT, and hence the gates of the transistors P2 and P5 are electrically connected to the power source VDD. Thus, the transistors P2 and P5 are turned OFF and deactivated. Similarly, the transistors N3 and N6 are turned ON in response to the mode signal MB, and the transistors N2 and N5 are turned OFF and deactivated. As a result, the P-channel cross-coupled transistor consisting of the transistors P1 and P4 and the N-channel cross-coupled transistor consisting of the transistors N1 and N4 are selected as the selected negative resistance circuits connected to the LC resonant circuit 1.

Moreover, since the mode signal MODE is Low level, the switch control signals SW01 to SW31 become Low level and thus the switches S30 to S33 and S40 to s43 are turned OFF. That is to say, the capacitor switch groups 43 and 44 are not incorporated into the resonant circuit, and only the capacitor switch groups 41 and 42 can be selected and incorporated into the resonant circuit. As a result, the oscillation frequency f_{vco} of the voltage-controlled oscillator 100 during the high frequency mode depends on the total capacitance value of the capacitors selected only from the capacitor switch groups 41 and 42.

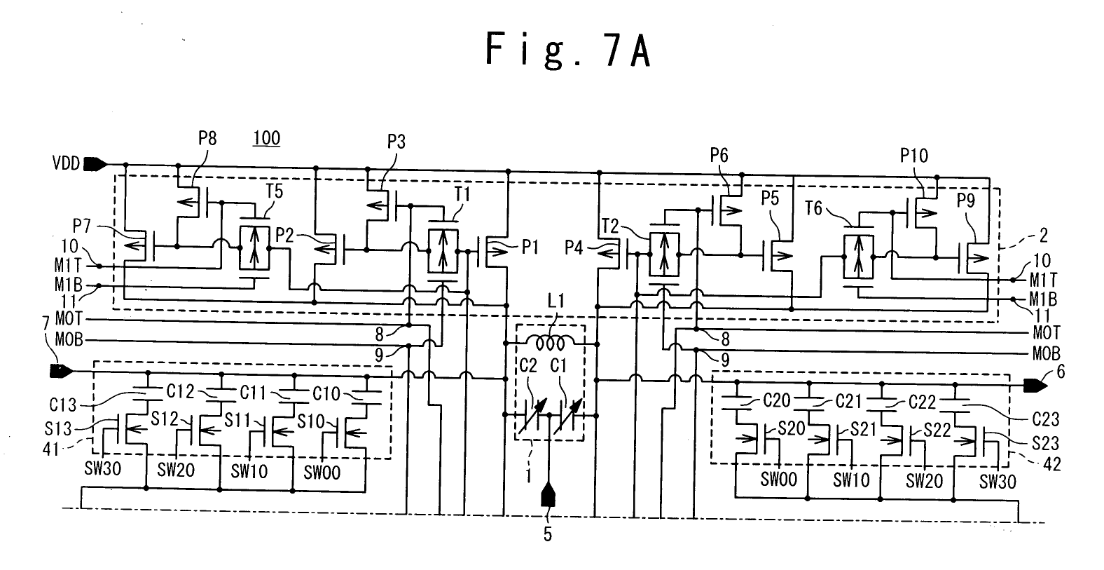

FIG. 6 shows a relationship between the oscillation frequency f_{vco} of the voltage-controlled oscillator 100 and the control voltage input to the control voltage input terminal 5, which was obtained by a simulation. As shown in FIG. 6, the oscillation frequency f_{vco} of the voltage-controlled oscillator 100 in the high frequency mode can be changed within a frequency range indicated by the MODE “L”. It is possible to change the oscillation frequency f_{vco} distinctly by using the switch control signals SW00 to SW30, i.e., by changing the number of the selected capacitors incorporated into the resonant circuit. For example, (A) the oscillation frequency f_{vco} indicated by “A” is obtained by selecting the capacitors C10 and C20, (B) the oscillation frequency f_{vco} indicated by “B” is obtained by selecting the capacitors C10, C11, C20 and C21, (C) the oscillation frequency f_{vco} indicated by “C” is obtained by selecting the capacitors C10 to C12 and C20 to C22, and (D) the oscillation frequency f_{vco} indicated by “C” is obtained by selecting the capacitors C10 to C13 and C20 to C23. Here, the respective capacitance values of the capacitors C10 to C13 may be the same or different from each other. The respective capacitance values of the capacitors C20 to C23 may be the same or different from each other. In order to make the control of the oscillation frequency easy, it is preferable that the capacitance values of the capacitors associated with the same switch control signal are the same.

Moreover, the capacitance values of the variable capacitors C1 and C2 can be changed by changing the control voltage input to the control voltage input terminal 5. Therefore, as shown in FIG. 6, the oscillation frequency f_{vco} can be continuously changed in accordance with the control voltage, which makes a finer control of the oscillation frequency f_{vco} possible.

As shown in FIG. 6, the voltage-controlled oscillator 100 according to the present embodiment is able to control the oscillation frequency f_{vco} within a higher frequency range in the high frequency mode. For example, the oscillation frequency f_{vco} can be controlled in a 6.4 GHz band and within a variable range of ±5 to 10% from the center frequency of 6.4 GHz.

### (Low Frequency Mode)

In the case of the low frequency mode, the mode signal MODE of High level is input to the selection circuit 107. Therefore, the mode signal MT of High level and the mode signal MB of Low level are input to the voltage-controlled oscillation circuit 106. In this case, the transmission gates T1 to T4 are turned ON (Low-impedance) in response to the mode signals MT and MB, and hence the gates of the transistors P2, P5, N2 and N5 are electrically connected to the gates of the transistors P1, P4, N1 and N4, respectively. In other words, not only the gates of the transistors P1 and N1 but also the gates of the transistors P2 and N2 are electrically connected to the output terminal 6. Similarly, not only the gates of the transistors P4 and N4 but also the gates of the transistors P5 and N5 are electrically connected to the output terminal 7. Also, the transistors P3 and P6 are turned OFF in response to the mode signal MT, and the transistors N3 and N6 are turned OFF in response to the mode signal MB. As a result, the P-channel cross-coupled transistor consisting of the transistors P1 and P4, the P-channel cross-coupled transistor consisting of the transistors P2 and P5, the N-channel cross-coupled transistor consisting of the transistors N1 and N4, and the N-channel cross-coupled transistor consisting of the transistors N2 and N5 are selected as the selected negative resistance circuits connected to the LC resonant circuit 1. Note that the number of the selected negative resistance circuits for supplying the power to the resonant circuit is increased as compared with the high frequency mode, which can enhance the driving capability.

As described above, when the mode signal MODE is High level, the signal levels of the switch control signals SW01 to SW31 are the same as those of the switch control signals SW00 to SW30, respectively. For example, the switch control signal SW01 becomes High level when the switch control signal SW00 is High level. Therefore, all of the capacitor switch groups 41 to 44 can be selected and incorporated into the resonant circuit. The oscillation frequency f_{vco} of the voltage-controlled oscillator 100 during the low frequency mode depends on the total capacitance value of the capacitors selected from the capacitor switch groups 41 to 44. In this case, the number (total capacitance) of the selected capacitors incorporated into the resonant circuit can be larger than that in the high frequency mode. Therefore, the voltage-controlled oscillator 100 is able to oscillate at a lower oscillation frequency f_{vco}.

As shown in FIG. 6, the oscillation frequency f_{vco} of the voltage-controlled oscillator 100 in the low frequency mode can be changed within a frequency range indicated by the MODE “H”. It is possible to change the oscillation frequency f_{vco} distinctly by using the switch control signals SW00 to SW30 and SW01 to SW31, i.e., by changing the number of the selected capacitors incorporated into the resonant circuit. For example, (E) the oscillation frequency f_{vco} indicated by “E” is obtained by selecting the capacitors C10, C20, C30 and C40, (F) the oscillation frequency f_{vco} indicated by “F” is obtained by selecting the capacitors C10, C11, C20, C21, C30, C31, C40 and C41, (G) the oscillation frequency f_{vco} indicated by “G” is obtained by selecting the capacitors C10 to C12, C20 to C22, C30 to C32 and C40 to C43, and (H) the oscillation frequency f_{vco} indicated by “H” is obtained by selecting the capacitors C10 to C13, C20 to C23, C30 to C33 and C40 to C43. Here, the respective capacitance values of the capacitors C10 to C13 may be the same or different from each other. The respective capacitance values of the capacitors C20 to C23 may be the same or different from each other. The respective capacitance values of the capacitors C30 to C33 may be the same or different from each other. The respective capacitance values of the capacitors C40 to C43 may be the same or different from each other.

The capacitance value of each capacitor (C30 to C33, C40 to C43) in the capacitor switch groups 43 and 44 may be larger than the capacitance value of each capacitor (C10 to C13, C20 to C23) in the capacitor switch groups 41 and 42. In this case, it is possible to provide a “gap” between the frequency variable range in the high frequency mode and a variable frequency range in the low frequency mode, as shown in FIG. 6 (between the D and the E in FIG. 6). Of course, such a gap is not necessarily provided. It is also possible to eliminate the gap or overlap those two frequency variable ranges by appropriately setting the capacitance values of the capacitors in the capacitor switch groups 41 to 44.

Moreover, as in the high frequency mode, the capacitance values of the variable capacitors C1 and C2 can be changed by changing the control voltage input to the control voltage input terminal 5. Therefore, as shown in FIG. 6, the oscillation frequency f_{vco} can be continuously changed in accordance with the control voltage, which makes a finer control of the oscillation frequency f_{vco} possible.

As shown in FIG. 6, the voltage-controlled oscillator 100 according to the present embodiment is able to control the oscillation frequency f_{vco} within a lower frequency range in the low frequency mode. For example, the oscillation frequency f_{vco} can be controlled in a 4.8 GHz band and within a variable range of ±5 to 10% from the center frequency of 4.8 GHz.

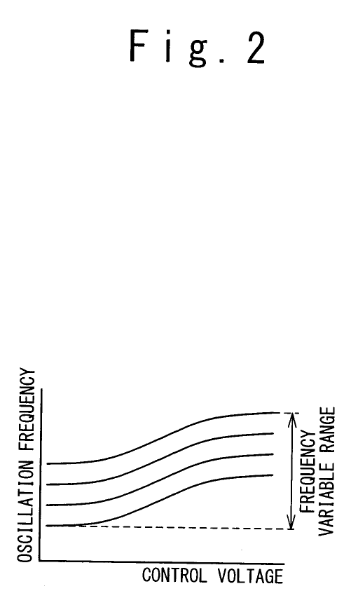

As described above, the voltage-controlled oscillator 100 according to the present embodiment is provided with the plurality of capacitor switch groups 41 to 44 and is able to select the capacitor switch group incorporated into the resonant circuit. Consequently, it becomes possible to control the oscillation frequency f_{vco} within a total variable range of ±25 to 30% as shown in FIG. 6. In other words, the frequency variable range is enlarged as is obvious from the comparison between FIG. 2 and FIG. 6. Furthermore, in the low frequency mode where many capacitors can be incorporated into the resonant circuit, the number of the selected negative resistance circuits for supplying the power to the resonant circuit is increased in order to enhance the driving capability.

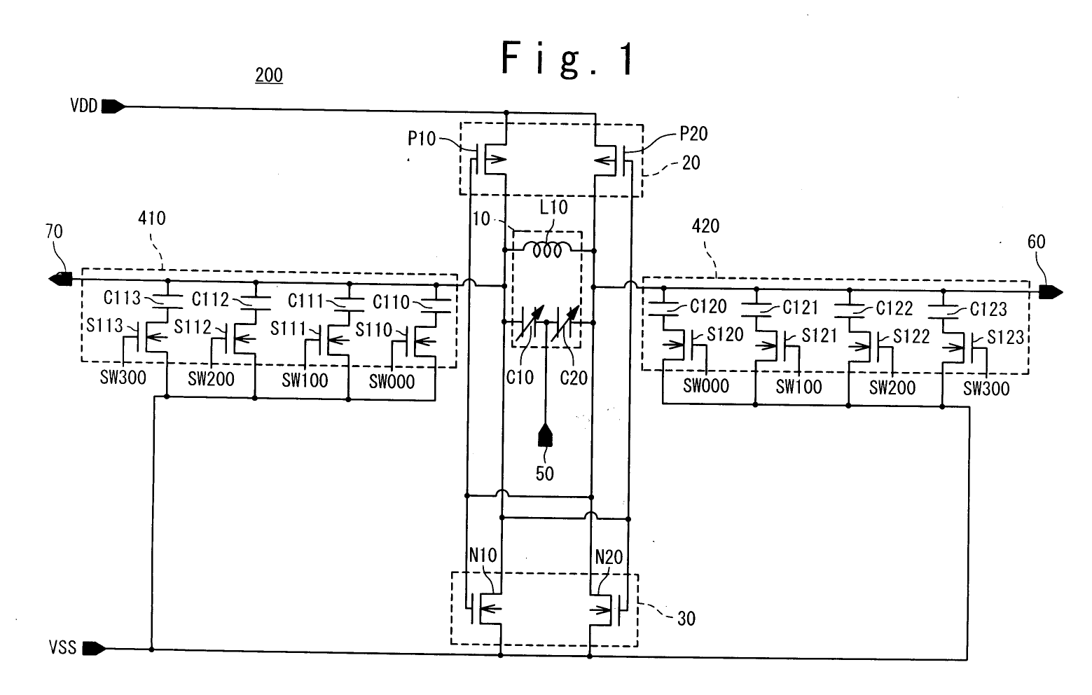

In recent years, there is a case where a product is required to support various applications. However, the voltage-controlled oscillator 200 shown in FIG. 1 can not meet the requirement because the variable range of the oscillation frequency is small (about ±10% at a maximum). One possible solution is to provide a single product with a plurality of voltage-controlled oscillators whose oscillation frequencies are different from each other for supporting the respective applications, so that the single product selectively can use any of the plurality of voltage-controlled depending on a situation. However, this leads to large increase in a chip size and cost of manufacturing.

Whereas, according to the voltage-controlled oscillator 100 in the present embodiment, the variable range of the oscillation frequency f_{vco} is enlarged. Furthermore, the selection circuit 107 used for controlling the oscillation frequency f_{vco} consists of simple logic circuits and has a simple configuration. It is therefore possible to suppress the chip size and the cost of manufacturing.

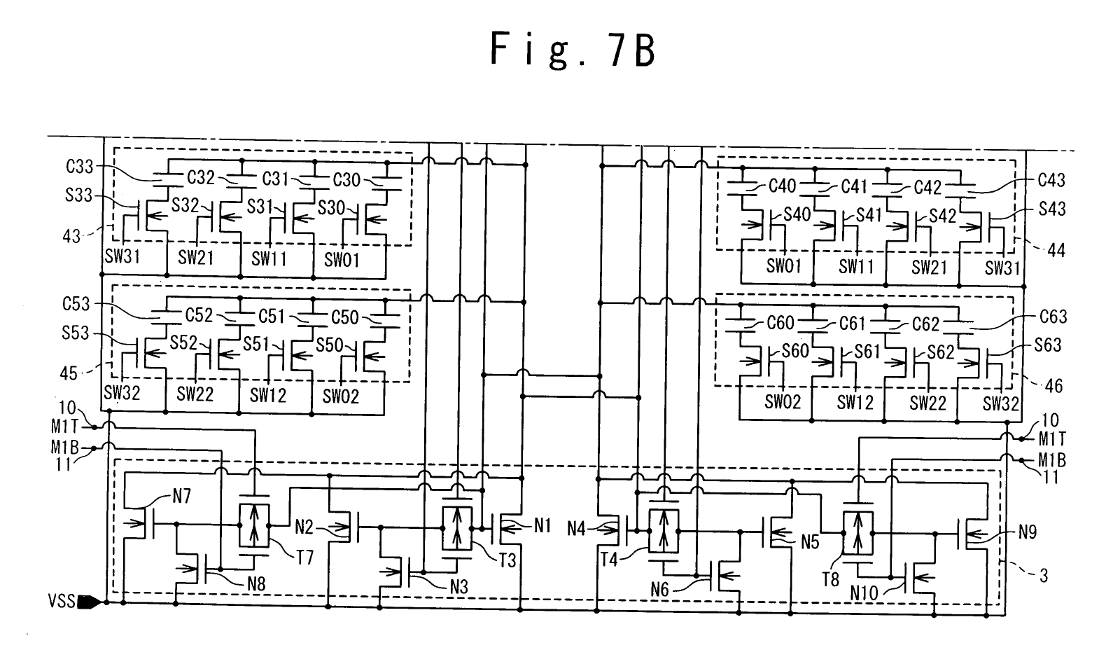

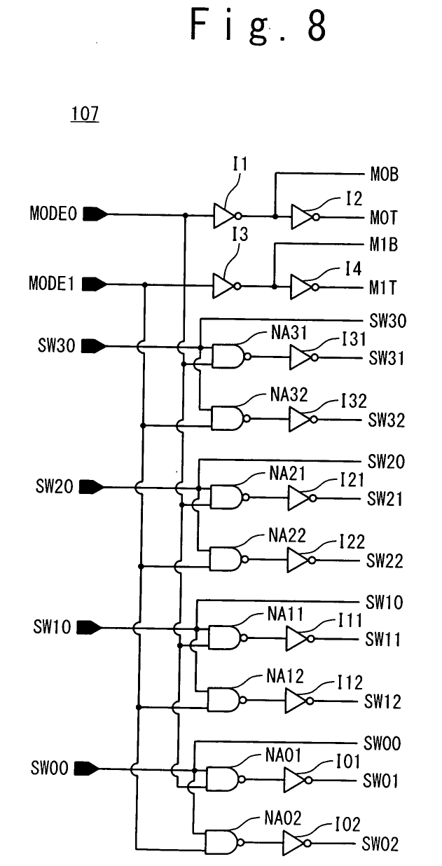

In the above-mentioned embodiment, four (two pairs of) capacitor switch groups are provided in the voltage-controlled oscillator 100. However, the number of the capacitor switch groups is not limited to four and can be more (it is preferable that the capacitor switch groups are provided in pairs). A case where six (three pairs of) capacitor switch groups 41 to 46 are provided will be described below with reference to FIGS. 7A, 7B and 8. The same reference numerals are given to the same components as those described in the foregoing FIGS. 4 and 5, and an overlapping description will be omitted as appropriate.

FIGS. 7A and 7B are circuit diagrams showing a configuration example of the voltage-controlled oscillation circuit 106. As shown in FIGS. 7A and 7B, two (a pair of) capacitor switch groups 45 and 46 are added to the configuration shown in FIG. 4. In this case, the number (total capacitance values) of the selected capacitors incorporated into the resonant circuit can be larger than the above-mentioned configuration. It is therefore preferable to provide the P-channel cross-coupled transistor 2 and the N-channel cross-coupled transistor 3 with further more negative resistance circuits. In the case of FIGS. 7A and 7B, a P-channel cross-coupled transistor (P-channel MOS transistors P7 and P9) and an N-channel cross-coupled transistor (N-channel MOS transistors N7 and N9) that serves as negative resistance circuits are added. Moreover, the first switch circuit for controlling an electrical connection between the added negative resistance circuit and the LC resonant circuit 1 is further added to each of the P-channel cross-coupled transistor 2 and the N-channel cross-coupled transistor 3. More specifically, P-channel MOS transistors P8 and P10 and transmission gates T5 and T6 are added to the P-channel cross-coupled transistor 2, which function as the first switch circuit for controlling the electrical connection of the P-channel MOS transistors P7 and P9 with the LC resonant circuit 1. Similarly, N-channel MOS transistors N8 and N10 and the transmission gates T7 and T8 are added to the N-channel cross-coupled transistor 3, which function as the first switch circuit for controlling the electrical connection of the N-channel MOS transistors N7 and N9 with the LC resonant circuit 1. Hereinafter, the P-channel transistors P7 to P10 are referred to as transistors P7 to P10, and the N-channel transistors N7 to N10 are referred to as transistors N7 to N10.

As shown in FIGS. 7A and 7B, a two-bit mode signal (M0T, M0B) and another two-bit mode signal (M1T, M1B) are input to the voltage-controlled oscillation circuit 106 having the six (three pairs of) capacitor switch groups 41 to 46. The mode signals M0T and M0B are complementary and input through the nodes 8 and 9, respectively. The mode signals M1T and M1B are complementary and input through the nodes 10 and 11, respectively.

Configurations and connection relationships of the transistors P7, P8, P9 and P10 and the transmission gates T5 and T6 are similar to those of the above-mentioned transistors P2, P3, P5 and P6 and the transmission gates T1 and T2. Gates of the transistors P8 and P10 are connected to the node 10, and the transistors P8 and P10 respectively control electrical connections of gates of the transistors P7 and P9 with the power source VDD in accordance with the mode signal M1T input to the node 10. Each of the transmission gates T5 and T6 is connected to the nodes 10 and 11. In accordance with the mode signals M1T and M1B, the transmission gates T5 and T6 control electrical connections of the gates of the transistors P7 and P9 with the output terminals 6 and 7, respectively.

Configurations and connection relationships of the transistors N7, N8, N9 and N10 and the transmission gates T7 and T8 are similar to those of the above-mentioned transistors N2, N3, N5 and N6 and the transmission gates T3 and T4. Gates of the transistors N8 and N10 are connected to the node 11, and the transistors N8 and N10 respectively control electrical connections of gates of the transistors N7 and N9 with the power source VSS in accordance with the mode signal M1B input to the node 11. Each of the transmission gates T7 and T8 is connected to the nodes 10 and 11. In accordance with the mode signals M1T and M1B, the transmission gates T7 and T8 control electrical connections of the gates of the transistors N7 and N9 with the output terminals 6 and 7, respectively.

A configuration of each of the capacitor switch groups 45 and 46 is similar to that of another capacitor switch group. The capacitor switch group 45 includes capacitors C50 to C53 connected to the output terminal 7, and switches S50 to S53 connected between the power source VSS and the respective capacitors C50 to C53. The switches S50 to S53 as the second switch are ON/OFF controlled by switch control signals SW02 to SW32, respectively. Similarly, the capacitor switch group 46 includes capacitors C60 to C63 connected to the output terminal 6, and switches S60 to S63 connected between the power source VSS and the respective capacitors C60 to C63. The switches S60 to S63 as the second switch are ON/OFF controlled by the switch control signals SW02 to SW32, respectively.

FIG. 8 is a circuit diagram showing a configuration example of the selection circuit 107. The selection circuit 107 is configured to generate the mode signals M0T, M0B, M1T, M1B, the switch control signals SW00 to SW30, SW01 to SW31 and SW02 to SW32 based on a plurality of mode signals (MODE0 and MODE1) and the switch control signals SW00 to SW30. As shown in FIG. 8, inverters I3 and 14, NAND gates NA02 to NA32 and inverters I02 to I32 are added to the above-mentioned selection circuit 107 shown in FIG. 5. The inverter I3 receives the mode signal MODE1 and outputs the mode signal M1B. The inverter I4 receives the mode signal M1B and outputs the mode signal M1T. The NAND gates NA02 to NA32 respectively receive the switch control signals SW00 to SW30 together with the mode signal MODE1 and output results of the negative AND operation. The inverters I02 to I32 respectively receive the output signals from the NAND gates NA02 to NA32 and output the switch control signals SW02 to SW32. The mode signal MODE0 in FIG. 8 corresponds to the mode signal MODE in FIG. 5. The inverter I1 receives the mode signal MODE0 and outputs the mode signal MOB. The inverter I2 receives the mode signal MOB and outputs the mode signal M0T. The selection circuit 107 thus constructed generates the switch control signals SW01 to SW31 based on the mode signal MODE0 and the switch control signals SW00 to SW30, and generates the switch control signals SW02 to SW32 based on the mode signal MODE1 and the switch control signals SW00 to SW30.

The voltage-controlled oscillator 100 thus constructed is able to operate in four operation modes depending on combinations of the mode signal MODE0 and the mode signal MODE1. A set of the selected capacitor groups to be incorporated into the resonant circuit can be changed between the four operation modes depending on the combinations of the mode signals MODE0 and MODE1. Consequently, the voltage-controlled oscillator 100 is able to control the oscillation frequency f_{vco} within a further wider variable range.

The configuration of the voltage-controlled oscillator 100 is not limited to the above-described embodiment. For example, although the switches (S10 to S13, S20 to S23, S30 to S33, S40 to S43, S50 to S53 and S60 to S63) are exemplified by the N-channel MOS transistors in the above description, P-channel MOS transistors may be used as those switches. In this case, those switches are connected between the power source VDD and the respective capacitors (C10 to C13, C20 to C23, C30 to C33, C40 to C43, C50 to C53 and C60 to C63). The driving capabilities of the respective transistors serving as the plurality of negative resistance circuits may be the same or may be different from each other. The number of the capacitors included in one capacitor switch group is arbitrary and not limited to four. The selection circuit 107 may be provided outside of the voltage-controlled oscillator 100.

It is apparent that the present invention is not limited to the above embodiments and may be modified and changed without departing from the scope and spirit of the invention.

What is claimed is:

1. A voltage-controlled oscillator comprising:
an LC resonant circuit including an inductor and a variable capacitor that are connected in parallel between a pair of output terminals, wherein capacitance of said variable capacitor varies depending on an input voltage;
a plurality of negative resistance circuits provided between a power source and said LC resonant circuit;
a plurality of capacitor groups;
a first switch circuit configured to select an arbitrary number of negative resistance circuit from said plurality of negative resistance circuits; and
a second switch circuit configured to select an arbitrary number of capacitor group from said plurality of capacitor groups,
wherein said LC resonant circuit and said selected capacitor group constitute a resonant circuit,
wherein said resonant circuit is electrically connected to said power source through said selected negative resistance circuit, oscillates at an oscillation frequency depending on total capacitance of said resonant circuit, and outputs a differential signal of said oscillation frequency from said pair of output terminals.

2. The voltage-controlled oscillator according to claim 1,
wherein said first switch circuit selects said negative resistance circuit whose number corresponds to the number of said selected capacitor group.

3. The voltage-controlled oscillator according to claim 1,
wherein each of said plurality of capacitor groups includes a plurality of capacitors,
said second switch circuit selects an arbitrary number of capacitor from said plurality of capacitors in each of said selected capacitor group, and
said selected capacitor in each of said selected capacitor group and said LC resonant circuit constitute said resonant circuit.

4. The voltage-controlled oscillator according to claim 1,
wherein the voltage-controlled oscillator operates in a plurality of modes, and
said second switch circuit selects said capacitor group whose number is different between said plurality of modes.

5. The voltage-controlled oscillator according to claim 4,
wherein said first switch circuit selects said negative resistance circuit whose number is different between said plurality of modes and corresponds to the number of said selected capacitor group.

6. The voltage-controlled oscillator according to claim 4,
wherein each of said plurality of capacitor groups includes a plurality of capacitors,
said second switch circuit selects an arbitrary number of capacitor from said plurality of capacitors in each of said selected capacitor group, and
said selected capacitor in each of said selected capacitor group and said LC resonant circuit constitute said resonant circuit.

7. The voltage-controlled oscillator according to claim 6, further comprising a selection circuit configured to generate a plurality of switch control signals which are respectively related to said plurality of capacitors in each of said plurality of capacitor groups and specify said selected capacitor group and said selected capacitor,
wherein said second switch circuit selects said capacitor group and said capacitor in response to said plurality of switch control signals.

8. The voltage-controlled oscillator according to claim 7,
wherein said selection circuit receives a mode signal specifying an operation mode among said plurality of modes and generates said plurality of switch control signals based on said mode signal such that the number of said selected capacitor group depends on said mode signal.

9. The voltage-controlled oscillator according to claim 8,
wherein said first switch circuit selects said negative resistance circuit based on said mode signal such that the number of said selected negative resistance circuit depends on said mode signal.

10. The voltage-controlled oscillator comprising according to claim 1,
wherein said first switch circuit includes a first transmission gate and a second transmission gate, and said plurality of negative resistance circuits include a first negative resistance circuit,
wherein said first negative resistance circuit comprises:
a first transistor whose drain is connected to said LC resonant circuit and one of said pair of output terminals, whose source is connected to said power source, and whose gate is connected to said LC resonant circuit and the other of said pair of output terminals through said first transmission gate; and
a second transistor whose drain is connected to said LC resonant circuit and said other output terminal, whose source is connected to said power source, and whose gate is connected to said LC resonant circuit and said one output terminal through said second transmission gate,
wherein said first switch circuit turns on said first transmission gate and said second transmission gate when selecting said first negative resistance circuit.

11. A method of operating a voltage-controlled oscillator which has an LC resonant circuit including an inductor and a variable capacitor that are connected in parallel between a pair of output terminals, comprising:
selecting an arbitrary number of capacitor group from a plurality of capacitor groups such that said LC resonant circuit and said selected capacitor group constitute a resonant circuit;
selecting an arbitrary number of negative resistance circuit from a plurality of negative resistance circuits such that said resonant circuit is electrically connected to a power source through said selected negative resistance circuit;
changing capacitance of said variable capacitor depending on an input voltage;
oscillating by said resonant circuit at an oscillation frequency depending on total capacitance of said resonant circuit; and
outputting a differential signal of said oscillation frequency from said pair of output terminals.

12. The method according to claim 11,
wherein said negative resistance circuit is selected such that the number of said selected negative resistance circuit corresponds to the number of said selected capacitor group.

13. The method according to claim 11,
wherein each of said plurality of capacitor groups includes a plurality of capacitors,
an arbitrary number of capacitor is selected from said plurality of capacitors in each of said selected capacitor group, and
said selected capacitor in each of said selected capacitor group and said LC resonant circuit constitute said resonant circuit.

14. The method according to claim 11, further comprising: changing the number of said selected capacitor group depending on an operation mode of the voltage-controlled oscillator.
